(19) United States
(12) Patent Application Publication
(10) Pub. No.: US 2006/0090791 A1
(43) Pub. Date: May 4, 2006

(54) Photovoltaic cell with mesh electrode

(76) Inventors: Russell Gaudiana, Merrimack, NH (US); Alan Montello, West Newbury, MA (US)

Correspondence Address: Konarka Technologies, Inc., Suite 12, 116 John Street, Lowell, MA, 01852, US

(21) Appl. No.: 11/261,197

(22) Filed: Oct. 28, 2005

Related U.S. Application Data
(63) Continuation-in-part of application No. 10/723,554, filed on Nov. 26, 2003.
Application No. 10/723,554 is a continuation-in-part of application No. 10/395,823, filed on Mar. 24, 2003.

(51) Int. Cl. H01L 31/00

(52) U.S. Cl. 136/256; 438/98

(57) ABSTRACT

Photovoltaic cells that have a mesh electrode, as well as related systems, methods and components, are disclosed.

### CROSS-REFERENCE TO RELATED APPLICATION

This application is a continuation-in-part of, and claims priority under 35 U.S.C. §120 to, U.S. patent application Ser. No. 10/723,554, filed Nov. 26, 2003, and entitled “Photovoltaic Cells Utilizing Mesh Electrodes,” which in turn is a continuation-in-part of and claims priority to U.S. patent application Ser. No. 10/395,823, filed Mar. 24, 2003, and entitled “Photovoltaic Cells Utilizing Mesh Electrodes,” the entire contents of which are hereby incorporated by reference.

### TECHNICAL FIELD

The invention relates to photovoltaic cells that have a mesh electrode, as well as related systems, methods and components.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material. As a result, the ability of one or both of the electrodes to transmit light (e.g., light at one or more wavelengths absorbed by a photoactive material) can limit the overall efficiency of a photovoltaic cell. In many photovoltaic cells, a film of semiconductive material (e.g., indium tin oxide) is used to form the electrode(s) through which light passes because, although the semiconductive material may have a lower electrical conductivity than electrically conductive materials, the semiconductive material can transmit more light than many electrically conductive materials.

There is an increasing interest in the development of photovoltaic technology due primarily to a desire to reduce consumption of and dependency on fossil fuel-based energy sources. Photovoltaic technology is also viewed by many as being an environmentally friendly energy technology. However, for photovoltaic technology to be a commercially feasible energy technology, the material and manufacturing costs of a photovoltaic system (a system that uses one or more photovoltaic cells to convert light to electrical energy) should be recoverable over some reasonable time frame. But, in some instances the costs (e.g., due to materials and/or manufacture) associated with practically designed photovoltaic systems have restricted their availability and use.

### SUMMARY

The invention relates to photovoltaic cells that have a mesh electrode, as well as related systems, methods and components. The mesh electrode is formed of a material that provides good electrical conductivity (typically an electrically conductive material, but semiconductive materials may also be used), and the mesh electrode has an open area that is large enough to transmit enough light so that the photovoltaic cell captures most of the transmitted light. An example of the mesh electrode is a grid electrode.

In one aspect, the invention features a photovoltaic cell that includes two electrodes and an active layer between the electrodes. At least one of the electrodes is in the form of a mesh (e.g., a grid). The active layer includes an electron acceptor material and an electron donor material.

In another aspect, the invention features a system that includes a plurality of photovoltaic cells, with each of the photovoltaic cells including two electrodes and an active layer between the electrodes. At least one of the electrodes is in the form of a mesh (e.g., a grid). The active layer includes an electron acceptor material and an electron donor material. In some embodiments, two or more of the photovoltaic cells are electrically connected in parallel. In certain embodiments, two or more of the photovoltaic cells are electrically connected in series. In certain embodiments, two or more of the photovoltaic cells are electrically connected in parallel, and two or more different photovoltaic cells are electrically connected in series.

In a further aspect, the invention features a photovoltaic cell that includes first and second electrodes, an active layer between the first and second electrodes, a hole blocking layer between the first electrode and the active layer, and a hole carrier layer between the mesh electrode and the active layer. At least one of the electrodes is in the form of a mesh. The active layer includes an electron acceptor material and an electron donor material.

In another aspect, the invention features a system that includes a plurality of photovoltaic cells, with each of the photovoltaic cells including first and second electrodes, an active layer between the first and second electrodes, a hole blocking layer between the first electrode and the active layer, and a hole carrier layer between the second electrode and the active layer. At least one of the electrodes is in the form of a mesh. The active layer includes an electron acceptor material and an electron donor material. In some embodiments, two or more of the photovoltaic cells are electrically connected in parallel. In certain embodiments, two or more of the photovoltaic cells are electrically connected in series. In certain embodiments, two or more of the photovoltaic cells are electrically connected in parallel, and two or more different photovoltaic cells are electrically connected in series.

Embodiments can include one or more of the following aspects.

The mesh electrode can be a cathode or an anode. In some embodiments, a photovoltaic cell has a mesh cathode and a mesh anode.

The mesh electrode can be formed of wires. The wires can be formed of an electrically conductive material, such as an electrically conductive metal, an electrically conductive alloy, or an electrically conductive polymer. The wires can include a coating of an electrically conductive material (an electrically conductive metal, an electrically conductive alloy, or an electrically conductive polymer).

The mesh electrode can be, for example, an expanded mesh or a woven mesh. The mesh can be formed of an electrically conductive material (an electrically conductive metal, an electrically conductive alloy, or an electrically conductive polymer). The mesh can include a coating of an electrically conductive material (an electrically conductive metal, an electrically conductive alloy, or an electrically conductive polymer).

The electron acceptor material can be, for example, formed of fullerenes, inorganic nanoparticles, discotic liquid crystals, carbon nanorods, inorganic nanorods, oxadiazoles, or polymers containing moieties capable of accepting electrons or forming stable anions (e.g., polymers containing CN groups, polymers containing CF₃ groups). In some embodiments, the electron acceptor material is a substituted fullerene.

The electron donor material can be formed of discotic liquid crystals and conjugated polymers, such as, polythiophenes, polyphenylenes, polyphenylvinylenes, polysilanes, polythienylvinylenes, polyisothianaphthalenes, and homopolymers and co-polymers thereof. In some embodiments, the electron donor material is poly(3-hexylthiophene).

A photovoltaic cell can further include a hole blocking layer between the active layer and an anode (e.g., a mesh anode or a non-mesh anode). The hole blocking layer can be formed of, for example, LiF or metal oxides.

A photovoltaic cell can also include a hole carrier layer between the active layer and the cathode (e.g., a mesh cathode or non-mesh cathode). The hole carrier layer can be formed of, for example, polythiophenes, polyanilines, and/or polyvinylcarbazoles, or polyions of one or more of these polymers.

In some embodiments, the hole carrier layer is in contact with a substrate that supports that cathode.

In certain embodiments, the photovoltaic cell further includes an adhesive material between the substrate that supports the cathode and the hole carrier layer. In general, an adhesive material can adhere material layers in contact with the adhesive during standard operating conditions of a photovoltaic cell. In some embodiments, an adhesive includes one or more thermoplastics, thermosets, or pressure sensitive adhesives.

In some embodiments, the photovoltaic cell or photovoltaic system is electrically connected to an external load.

Embodiments can provide one or more of the following advantages.

In some embodiments, a mesh electrode can provide good electrical conductivity because it is formed of an electrically conductive material (as opposed to a semiconductor material), while at the same time having a structure (e.g., a mesh structure) that allows a sufficient amount of light therethrough so that the photovoltaic cell is more efficient at converting light into electrical energy.

In certain embodiments, a mesh electrode can be sufficiently flexible to allow the mesh electrode to be incorporated in the photovoltaic cell using a continuous, roll-to-roll manufacturing process, thereby allowing manufacture of the photovoltaic cell at relatively high throughput.

Using one or more mesh electrodes can reduce the cost and/or complexity associated with manufacturing a photovoltaic cell.

A photovoltaic cell having one or more mesh electrodes can transfer energy in the form of light to energy in the form of electricity in a more efficient manner compared to certain semiconductive electrodes.

Other features and advantages will be apparent from the description, drawings and from the claims.

### DESCRIPTION OF DRAWINGS

FIG. 1 is a cross-sectional view of an embodiment of a photovoltaic cell;

FIG. 2 is an elevational view of an embodiment of a mesh electrode;

FIG. 3 is a cross-sectional view of the mesh electrode of 2;

FIG. 4 is a cross-sectional view of a portion of a mesh electrode;

FIG. 5 is a cross-sectional view of another embodiment of a photovoltaic cell;

FIG. 6 is a schematic of a system containing multiple photovoltaic cells electrically connected in series; and

FIG. 7 is a schematic of a system containing multiple photovoltaic cells electrically connected in parallel.

### DETAILED DESCRIPTION

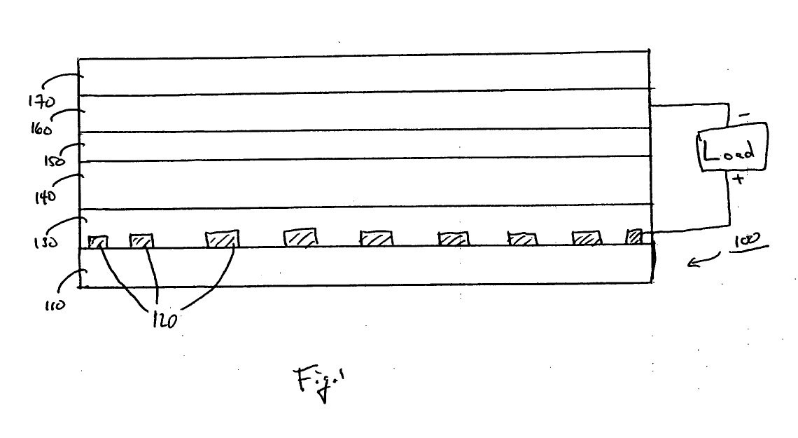

FIG. 1 shows a cross-sectional view of a photovoltaic cell 100 that includes a transparent substrate 110, a mesh cathode 120, a hole carrier layer 130, a photoactive layer (containing an electron acceptor material and an electron donor material) 140, a hole blocking layer 150, an anode 160, and a substrate 170.

In general, during use, light impinges on the surface of substrate 110, and passes through substrate 110, the openings in cathode 120 and hole carrier layer 130. The light then interacts with photoactive layer 140, causing electrons to be transferred from the electron donor material in layer 140 to the electron acceptor material in layer 140. The electron acceptor material then transmits the electrons through hole blocking layer 150 to anode 160, and the electron donor material transfers holes through hole carrier layer 130 to mesh cathode 120. Anode 160 and mesh cathode 120 are in electrical connection via an external load so that electrons pass from anode 160, through the load, and to cathode 120.

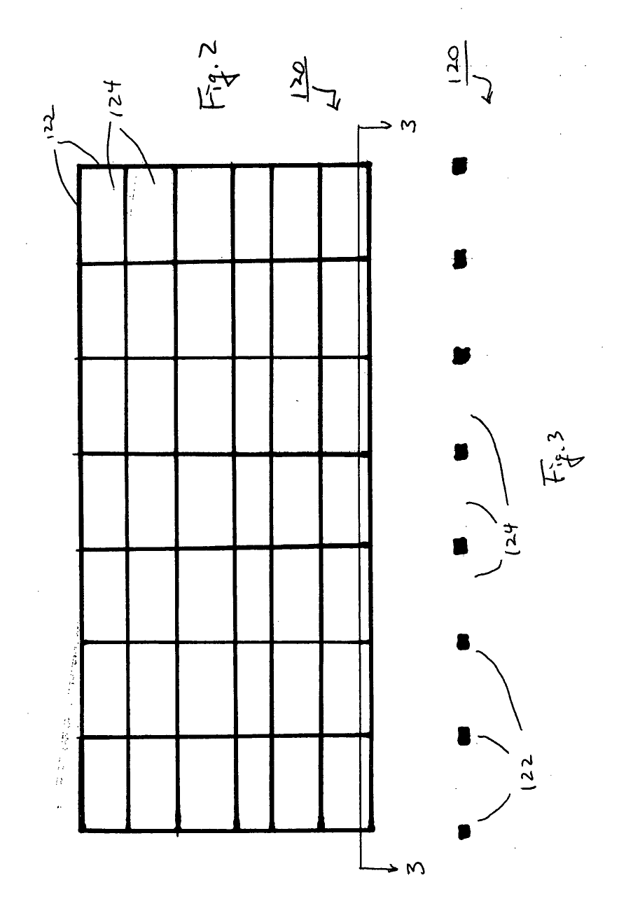

As shown in FIGS. 2 and 3, mesh cathode 120 includes solid regions 122 and open regions 124. In general, regions 122 are formed of electrically conducting material so that mesh cathode 120 can allow light to pass therethrough via regions 124 and conduct electrons via regions 122.

The area of mesh cathode 120 occupied by open regions 124 (the open area of mesh cathode 120) can be selected as desired. Generally, the open area of mesh cathode 120 is at least about 10% (e.g., at least about 20%, at least about 30%, at least about 40%, at least about 50%, at least about 60%, at least about 70%, at least about 80%) and/or at most about 99% (e.g., at most about 95%, at most about 90%, at most about 85%) of the total area of mesh cathode 120.

Mesh cathode 120 can be prepared in various ways. In some embodiments, mesh cathode 120 is a woven mesh formed by weaving wires of material that form solid regions 122. The wires can be woven using, for example, a plain weave, a Dutch, weave, a twill weave, a Dutch twill weave, or combinations thereof. In certain embodiments, mesh cathode 120 is formed of a welded wire mesh. In some embodiments, mesh cathode 120 is an expanded mesh formed. An expanded metal mesh can be prepared, for example, by removing regions 124 (e.g., via laser removal, via chemical etching, via puncturing) from a sheet of material (e.g., an electrically conductive material, such as a metal), followed by stretching the sheet (e.g., stretching the sheet in two dimensions). In certain embodiments, mesh cathode 120 is a metal sheet formed by removing regions 124 (e.g., via laser removal, via chemical etching, via puncturing) without subsequently stretching the sheet.

In certain embodiments, solid regions 122 are formed entirely of an electrically conductive material (e.g., regions 122 are formed of a substantially homogeneous material that is electrically conductive). Examples of electrically conductive materials that can be used in regions 122 include electrically conductive metals, electrically conductive alloys and electrically conductive polymers. Exemplary electrically conductive metals include gold, silver, copper, aluminum, nickel, palladium, platinum and titanium. Exemplary electrically conductive alloys include, alloys of gold, alloys of silver, alloys of copper, alloys of aluminum, alloys of nickel, alloys of palladium, alloys of platinum and alloys of titanium. Exemplary electrically conducting polymers include polythiophenes (e.g., poly(3,4-ethelynedioxythiophene) (PEDOT)), polyanilines (e.g., doped polyanilines), polypyrroles (e.g., doped polypyrroles). In some embodiments, combinations of electrically conductive materials are used. In some embodiments, solid regions 122 can have a resistivity less than about 3 ohm per square.

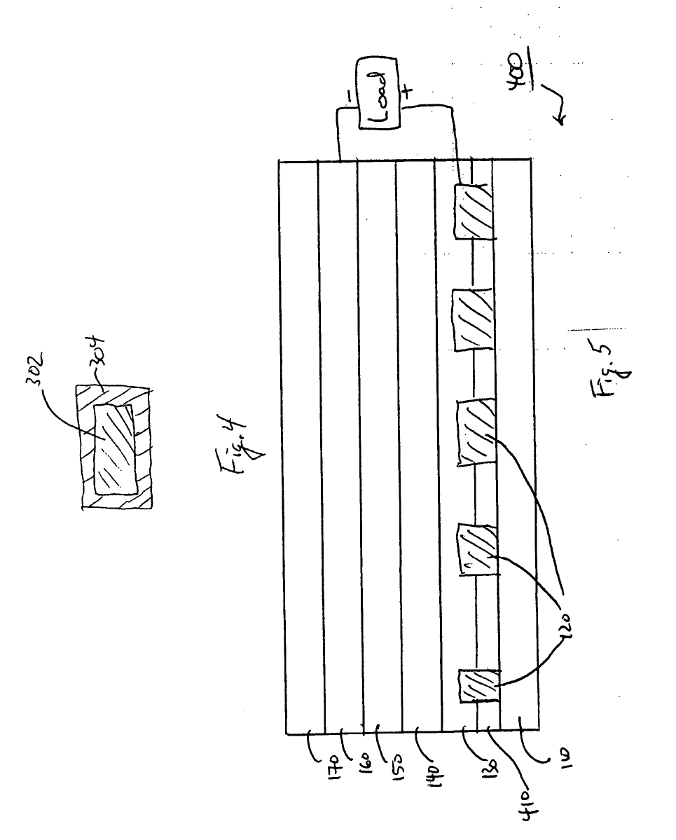

As shown in FIG. 4, in some embodiments, solid regions 122 are formed of a material 302 that is coated with a different material 304 (e.g., using metallization, using vapor deposition). In general, material 302 can be formed of any desired material (e.g., an electrically insulative material, an electrically conductive material, or a semiconductive material), and material 304 is an electrically conductive material. Examples of electrically insulative material from which material 302 can be formed include textiles, optical fiber materials, polymeric materials (e.g., a nylon) and natural materials (e.g., flax, cotton, wool, silk). Examples of electrically conductive materials from which material 302 can be formed include the electrically conductive materials disclosed above. Examples of semiconductive materials from which material 302 can be formed include indium tin oxide, fluorinated tin oxide, tin oxide and zinc oxide. In some embodiments, material 302 is in the form of a fiber, and material 304 is an electrically conductive material that is coated on material 302. In certain embodiments, material 302 is in the form of a mesh (see discussion above) that, after being formed into a mesh, is coated with material 304. As an example, material 302 can be an expanded metal mesh, and material 304 can be PEDOT that is coated on the expanded metal mesh.

Generally, the maximum thickness of mesh cathode 120 (i.e., the maximum thickness of mesh cathode 120 in a direction substantially perpendicular to the surface of substrate 110 in contact with mesh cathode 120) should be less than the total thickness of hole carrier layer 130. Typically, the maximum thickness of mesh cathode 120 is at least 0.1 micron (e.g., at least about 0.2 micron, at least about 0.3 micron, at least about 0.4 micron, at least about 0.5 micron, at least about 0.6 micron, at least about 0.7 micron, at least about 0.8 micron, at least about 0.9 micron, at least about one micron) and/or at most about 10 microns (e.g., at most about nine microns, at most about eight microns, at most about seven microns, at most about six microns, at most about five microns, at most about four microns, at most about three microns, at most about two microns).

While shown in FIG. 2 as having a rectangular shape, open regions 124 can generally have any desired shape (e.g., square, circle, semicircle, triangle, diamond, ellipse, trapezoid, irregular shape). In some embodiments, different open regions 124 in mesh cathode 120 can have different shapes.

Although shown in FIG. 3 as having square cross-sectional shape, solid regions 122 can generally have any desired shape (e.g., rectangle, circle, semicircle, triangle, diamond, ellipse, trapezoid, irregular shape). In some embodiments, different solid regions 122 in mesh cathode 120 can have different shapes. In embodiments where solid regions 122 have a circular cross-section, the cross-section can have a diameter in the range of about 5 microns to about 200 microns. In embodiments where solid regions 122 have a trapezoid cross-section, the cross-section can have a height in the range of about 0.1 micron to about 5 microns and a width in the range of about 5 microns to about 200 microns.

In some embodiments, mesh cathode 120 is flexible (e.g., sufficiently flexible to be incorporated in photovoltaic cell 100 using a continuous, roll-to-roll manufacturing process). In certain embodiments, mesh cathode 120 is semi-rigid or inflexible. In some embodiments, different regions of mesh cathode 120 can be flexible, semi-rigid or inflexible (e.g., one or more regions flexible and one or more different regions semi-rigid, one or more regions flexible and one or more different regions inflexible).

In general, mesh electrode 120 can be disposed on substrate 110. In some embodiments, mesh electrode 120 can be partially embedded in substrate 110.

Substrate 110 is generally formed of a transparent material. As referred to herein, a transparent material is a material which, at the thickness used in a photovoltaic cell 100, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. Exemplary materials from which substrate 110 can be formed include polyethylene terephthalates, polyimides, polyethylene naphthalates, polymeric hydrocarbons, cellulosic polymers, polycarbonates, polyamides, polyethers and polyether ketones. In certain embodiments, the polymer can be a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 megaPascals. In certain embodiments, different regions of substrate 110 can be flexible, semi-rigid or inflexible (e.g., one or more regions flexible and one or more different regions semi-rigid, one or more regions flexible and one or more different regions inflexible).

Typically, substrate 110 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Hole carrier layer 130 is generally formed of a material that, at the thickness used in photovoltaic cell 100, transports holes to mesh cathode 120 and substantially blocks the transport of electrons to mesh cathode 120. Examples of materials from which layer 130 can be formed include polythiophenes (e.g., PEDOT), polyanilines, polyvinylcarbazoles, polyphenylenes, polyphenylvinylenes, polysilanes, polythienylenevinylenes and/or polyisothianaphthanenes. In some embodiments, hole carrier layer 130 can include combinations of hole carrier materials.

In general, the distance between the upper surface of hole carrier layer 130 (i.e., the surface of hole carrier layer 130 in contact with active layer 140) and the upper surface of substrate 110 (i.e., the surface of substrate 110 in contact with mesh electrode 120) can be varied as desired. Typically, the distance between the upper surface of hole carrier layer 130 and the upper surface of mesh cathode 120 is at least 0.01 micron (e.g., at least about 0.05 micron, at least about 0.1 micron, at least about 0.2 micron, at least about 0.3 micron, at least about 0.5 micron) and/or at most about five microns (e.g., at most about three microns, at most about two microns, at most about one micron). In some embodiments, the distance between the upper surface of hole carrier layer 130 and the upper surface of mesh cathode 120 is from about 0.01 micron to about 0.5 micron.

Active layer 140 generally contains an electron acceptor material and an electron donor material.

Examples of electron acceptor materials include formed of fullerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups). In some embodiments, the electron acceptor material is a substituted fullerene (e.g., PCBM). In some embodiments, active layer 140 can include a combination of electron acceptor materials.

Examples of electron donor materials include discotic liquid crystals and conjugated polymers, such as, polythiophenes, polyphenylenes, polyphenylvinylenes, polysilanes, polythienylvinylenes, polyisothianaphthalenes, and homopolymers and co-polymers thereof. In some embodiments, the electron donor material is poly(3-hexylthiophene). In certain embodiments, active layer 140 can include a combination of electron donor materials.

Generally, active layer 140 is sufficiently thick to be relatively efficient at absorbing photons impinging thereon to form corresponding electrons and holes, and sufficiently thin to be relatively efficient at transporting the holes and electrons to layers 130 and 150, respectively. In certain embodiments, layer 140 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, layer 140 is from about 0.1 micron to about 0.2 micron thick.

Hole blocking layer 150 is general formed of a material that, at the thickness used in photovoltaic cell 100, transports electrons to anode 160 and substantially blocks the transport of holes to anode 160. Examples of materials from which layer 150 can be formed include LiF and metal oxides (e.g., zinc oxide, titanium oxide).

Typically, hole blocking layer 150 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Anode 160 is generally formed of an electrically conductive material, such as one or more of the electrically conductive materials noted above. In some embodiments, anode 160 is formed of a combination of electrically conductive materials.

Substrate 170 can be formed of a transparent material or a non-transparent material. For example, in embodiments in which photovoltaic cell uses light that passes through anode 160 during use, substrate 170 is desirably formed of a transparent material.

Exemplary materials from which substrate 170 can be formed include polyethylene terephthalates, polyimides, polyethylene naphthalates, polymeric hydrocarbons, cellulosic polymers, polycarbonates, polyamides, polyethers and polyether ketones. In certain embodiments, the polymer can be a fluorinated polymer. In some embodiments, combinations of polymeric materials are used. In certain embodiments, different regions of substrate 110 can be formed of different materials.

In general, substrate 170 can be flexible, semi-rigid or rigid. In some embodiments, substrate 170 has a flexural modulus of less than about 5,000 megaPascals. In certain embodiments, different regions of substrate 170 can be flexible, semi-rigid or inflexible (e.g., one or more regions flexible and one or more different regions semi-rigid, one or more regions flexible and one or more different regions inflexible). Generally, substrate 170 is substantially non-scattering.

Typically, substrate 170 is at least about one micron (e.g., at least about five microns, at least about 10 microns) thick and/or at most about 200 microns (e.g., at most about 100 microns, at most about 50 microns) thick.

Generally, substrate 170 can be colored or non-colored. In some embodiments, one or more portions of substrate 170 is/are colored while one or more different portions of substrate 170 is/are non-colored.

Substrate 170 can have one planar surface (e.g., the surface of substrate 170 on which light impinges in embodiments in which during use photovoltaic cell 100 uses light that passes through anode 160), two planar surfaces (e.g., the surface of substrate 170 on which light impinges in embodiments in which during use photovoltaic cell 100 uses light that passes through anode 160 and the opposite surface of substrate 170), or no planar surfaces. A non-planar surface of substrate 170 can, for example, be curved or stepped. In some embodiments, a non-planar surface of substrate 170 is patterned (e.g., having patterned steps to form a Fresnel lens, a lenticular lens or a lenticular prism).

FIG. 5 shows a cross-sectional view of a photovoltaic cell 400 that includes an adhesive layer 410 between substrate 110 and hole carrier layer 130.

Generally, any material capable of holding mesh cathode 130 in place can be used in adhesive layer 410. In general, adhesive layer 410 is formed of a material that is transparent at the thickness used in photovoltaic cell 400. Examples of adhesives include epoxies and urethanes. Examples of commercially available materials that can be used in adhesive layer 410 include Bynel™ adhesive (DuPont) and 615 adhesive (3M). In some embodiments, layer 410 can include a fluorinated adhesive. In certain embodiments, layer 410 contains an electrically conductive adhesive. An electrically conductive adhesive can be formed of, for example, an inherently electrically conductive polymer, such as the electrically conductive polymers disclosed above (e.g., PEDOT). An electrically conductive adhesive can be also formed of a polymer (e.g., a polymer that is not inherently electrically conductive) that contains one or more electrically conductive materials (e.g., electrically conductive particles). In some embodiments, layer 410 contains an inherently electrically conductive polymer that contains one or more electrically conductive materials.

In some embodiments, the thickness of layer 410 (i.e., the thickness of layer 410 in a direction substantially perpendicular to the surface of substrate 110 in contact with layer 410) is less thick than the maximum thickness of mesh cathode 120. In some embodiments, the thickness of layer 410 is at most about 90% (e.g., at most about 80%, at most about 70%, at most about 60%, at most about 50%, at most about 40%, at most about 30%, at most about 20%) of the maximum thickness of mesh cathode 120. In certain embodiments, however, the thickness of layer 410 is about the same as, or greater than, the maximum thickness of mesh cathode 130.

In general, a photovoltaic cell having a mesh cathode can be manufactured as desired.

In some embodiments, a photovoltaic cell can be prepared as follows. Electrode 160 is formed on substrate 170 using conventional techniques, and hole-blocking layer 150 is formed on electrode 160 (e.g., using a vacuum deposition process or a solution coating process). Active layer 140 is formed on hole-blocking layer 150 (e.g., using a solution coating process, such as slot coating, spin coating or gravure coating). Hole carrier layer 130 is formed on active layer 140 (e.g., using a solution coating process, such as slot coating, spin coating or gravure coating). Mesh cathode 120 is partially disposed in hole carrier layer 130 (e.g., by disposing mesh cathode 120 on the surface of hole carrier layer 130, and pressing mesh cathode 120). Substrate 110 is then formed on mesh cathode 120 and hole carrier layer 130 using conventional methods.

In certain embodiments, a photovoltaic cell can be prepared as follows. Electrode 160 is formed on substrate 170 using conventional techniques, and hole-blocking layer 150 is formed on electrode 160 (e.g., using a vacuum deposition or a solution coating process). Active layer 140 is formed on hole-blocking layer 150 (e.g., using a solution coating process, such as slot coating, spin coating or gravure coating). Hole carrier layer 130 is formed on active layer 140 (e.g., using a solution coating process, such as slot coating, spin coating or gravure coating). Adhesive layer 410 is disposed on hole carrier layer 130 using conventional methods. Mesh cathode 120 is partially disposed in adhesive layer 410 and hole carrier layer 130 (e.g., by disposing mesh cathode 120 on the surface of adhesive layer 410, and pressing mesh cathode 120). Substrate 110 is then formed on mesh cathode 120 and adhesive layer 410 using conventional methods.

While the foregoing processes involve partially disposing mesh cathode 120 in hole carrier layer 130, in some embodiments, mesh cathode 120 is formed by printing the cathode material on the surface of carrier layer 130 or adhesive layer 410 to provide an electrode having the open structure shown in the figures. For example, mesh cathode 120 can be printed using dip coating, extrusion coating, spray coating, inkjet printing, screen printing, and gravure printing. The cathode material can be disposed in a paste which solidifies upon heating or radiation (e.g., UV radiation, visible radiation, IR radiation, electron beam radiation). The cathode material can be, for example, vacuum deposited in a mesh pattern through a screen or after deposition it may be patterned by photolithography.

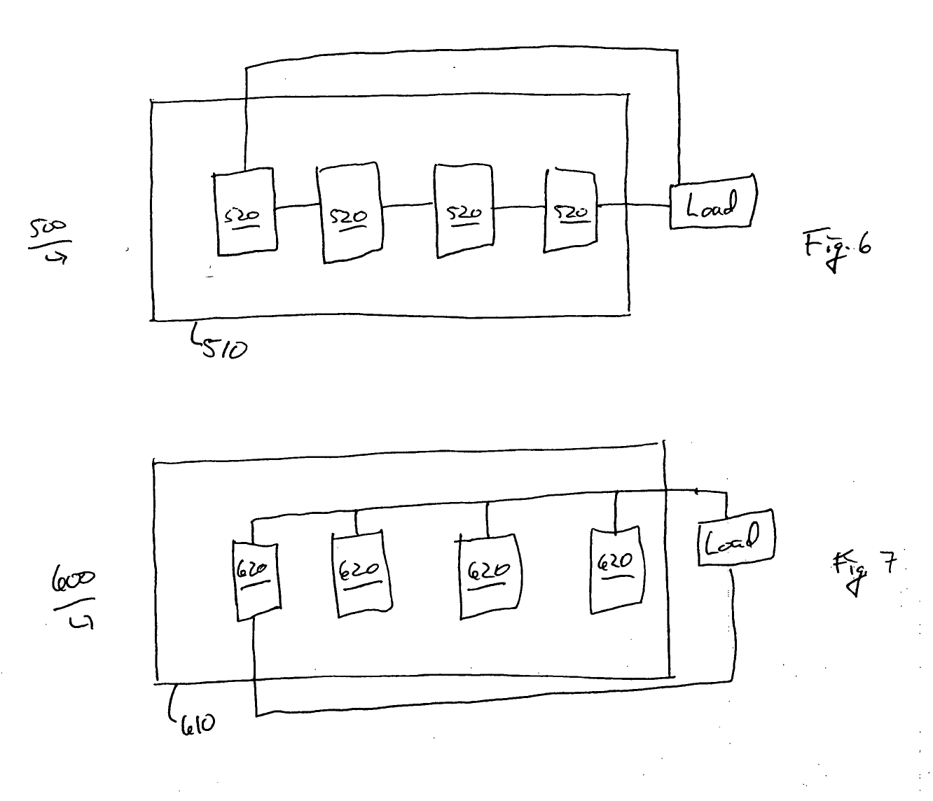

Multiple photovoltaic cells can be electrically connected to form a photovoltaic system. As an example, FIG. 6 is a schematic of a photovoltaic system 500 having a module 510 containing photovoltaic cells 520. Cells 520 are electrically connected in series, and system 500 is electrically connected to a load. As another example, FIG. 7 is a schematic of a photovoltaic system 600 having a module 610 that contains photovoltaic cells 620. Cells 620 are electrically connected in parallel, and system 600 is electrically connected to a load. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

In some embodiments, photovoltaic systems containing a plurality of photovoltaic cells can be fabricated using continuous manufacturing processes, such as roll-to-roll or web processes. In some embodiments, a continuous manufacturing process includes: forming a group of photovoltaic cell portions on a first advancing substrate; disposing an electrically insulative material between at least two of the cell portions on the first substrate; embedding a wire in the electrically insulative material between at least two photovoltaic cell portions on the first substrate; forming a group of photovoltaic cell portion on a second advancing substrate; combining the first and second substrates and photovoltaic cell portions to form a plurality of photovoltaic cells, in which at least two photovoltaic cells are electrically connected in series by the wire. In some embodiments, the first and second substrates can be continuously advanced, periodically advanced, or irregularly advanced.

While certain embodiments have been disclosed, other embodiments are also possible.

As another example, while cathodes formed of mesh have been described, in some embodiments a mesh anode can be used. This can be desirable, for example, when light transmitted by the anode is used. In certain embodiments, both a mesh cathode and a mesh anode are used. This can be desirable, for example, when light transmitted by both the cathode and the anode is used.

As an example, while embodiments have generally been described in which light that is transmitted via the cathode side of the cell is used, in certain embodiments light transmitted by the anode side of the cell is used (e.g., when a mesh anode is used). In some embodiments, light transmitted by both the cathode and anode sides of the cell is used (when a mesh cathode and a mesh anode are used).

As a further example, while electrodes (e.g., mesh electrodes, non-mesh electrodes) have been described as being formed of electrically conductive materials, in some embodiments a photovoltaic cell may include one or more electrodes (e.g., one or more mesh electrodes, one or more non-mesh electrodes) formed of a semiconductive material. Examples of semiconductive materials include indium tin oxide, fluorinated tin oxide, tin oxide and zinc oxide.

As an additional example, in some embodiments, one or more semiconductive materials can be disposed in the open regions of a mesh electrode (e.g., in the open regions of a mesh cathode, in the open regions of a mesh anode, in the open regions of a mesh cathode and the open regions of a mesh anode). Examples of semiconductive materials include tin oxide, fluorinated tin oxide, tin oxide and zinc oxide. Other semiconductive materials, such as partially transparent semiconductive polymers, can also be disposed in the open regions of a mesh electrode. For example, a partially transparent polymer can be a polymer which, at the thickness used in a photovoltaic cell, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. Typically, the semiconductive material disposed in an open region of a mesh electrode is transparent at the thickness used in the photovoltaic cell.

As another example, in certain embodiments, a protective layer can be applied to one or both of the substrates. A protective layer can be used to, for example, keep contaminants (e.g., dirt, water, oxygen, chemicals) out of a photovoltaic cell and/or to ruggedize the cell. In certain embodiments, a protective layer can be formed of a polymer (e.g., a fluorinated polymer).

As a further example, while certain types of photovoltaic cells have been described that have one or more mesh electrodes, one or more mesh electrodes (mesh cathode, mesh anode, mesh cathode and mesh anode) can be used in other types of photovoltaic cells as well. Examples of such photovoltaic cells include photoactive cells with an active material formed of amorphous silicon, cadmium selenide, cadmium telluride, copper indium sulfide, and copper indium gallium arsenide.

As an additional example, while described as being formed of different materials, in some embodiments materials 302 and 304 are formed of the same material.

As another example, although shown in FIG. 4 as being formed of one material coated on a different material, in some embodiments solid regions 122 can be formed of more than two coated materials (e.g., three coated materials, four coated materials, five coated materials, six coated materials.

Other embodiments are in the claims.

What is claimed is:

1. A method of preparing a photovoltaic cell, comprising:
supporting a mesh with a substrate, the mesh and the substrate forming at least a portion of a first electrode; and
supporting a photoactive layer with the mesh, the photoactive layer comprising an electron acceptor material and an electron donor material.

2. The method of claim 1, wherein the photovoltaic cell further includes a second electrode, the photoactive layer being disposed between the first and second electrodes.

3. The method of claim 1, wherein the mesh is disposed on the substrate using at least one process selected from the group consisting of dip coating, extrusion coating, spray coating, screen printing, and gravure printing.

4. The method of claim 1, wherein the mesh comprises a metallic material.

5. The method of claim 4, wherein the metallic material comprises at least one metal selected from the group consisting of silver, gold, copper, aluminum, palladium, platinum, and alloys thereof.

6. The method of claim 1, wherein the mesh comprises a trapezoid, semicircle, ellipse, rectangle, diamond, square, triangle, or irregularly shaped cross-section.

7. The method of claim 6, wherein the mesh comprises a trapezoid cross-section.

8. The method of claim 7, wherein the mesh has a height in the range of about 0.1 micron to about 5 microns and a width in the range of about 5 microns to about 200 microns.

9. The method of claim 1, wherein the mesh comprises a circular cross-section.

10. The method of claim 9, wherein the mesh has a diameter in the range of about 5 microns to about 200 microns.

11. The method of claim 1, wherein the mesh comprises metallic wire having a mesh opening in the range from about 50% to about 95%.

12. The method of claim 11, further comprising disposing a semiconductive material between the metallic wire.

13. The method of claim 12, wherein the semiconductive material comprises indium tin oxide.

14. The method of claim 12, wherein the semiconductive material comprises a partially transparent polymer.

15. The method of claim 1, wherein the mesh has a resistivity less than about 3 ohm per square.

16. The method of claim 1, wherein the mesh is partially embedded in the substrate.

17. The method of claim 1, wherein the mesh is flexible.

18. The method of claim 1, wherein the mesh is a grid.

19. The method of claim 1, wherein the substrate comprises glass.

20. The method of claim 1, wherein the substrate comprises a polyethylene naphthalate material or a polyethylene terephthalate material.

21. The method of claim 1, wherein the substrate comprises a flexible polymer material.

22. The method of claim 1, wherein the first electrode comprises an expanded metallic mesh electrode.

23. The method of claim 1, wherein the substrate transmits from about 60% to about 95% of incident light.

24. The method of claim 1, wherein the first electrode is a cathode.

25. The method of claim 1, wherein the second electrode comprises a metallic mesh.

26. The method of claim 1, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

27. The method of claim 1, wherein the electron acceptor material comprises a substituted fullerene.

28. The method of claim 1, wherein the electron donor material comprises discotic liquid crystals.

29. The method of claim 1, wherein the electron donor material comprises a material selected from the group consisting of polythiophenes, polyphenylenes, polyphenylvinylenes, polysilanes, polythienylvinylenes, polyisothianaphthalenes, and homopolymers and co-polymers thereof.

30. The method of claim 1, wherein the electron donor material comprises poly(3-hexylthiophene).

31. A method of preparing a module, comprising:
supporting a mesh with an advancing substrate, the mesh and the substrate forming at least a portion of each of a plurality of first electrodes; and
supporting a photoactive layer with the mesh, the photoactive layer comprising an electron acceptor material and an electron donor material.

32. The method of claim 31, wherein the module further includes a plurality of second electrodes, the photoactive layer being disposed between each of the first electrodes and each of the second electrodes to form a plurality of photovoltaic cells, at least two of the photovoltaic cells being electrically connected.

33. The method of claim 31, wherein the mesh is disposed on the advancing substrate using at least one process selected from the group consisting of dip coating, extrusion coating, spray coating, screen printing, and gravure printing.

34. The method of claim 31, wherein the advancing substrate is continuously advanced, periodically advanced, or irregularly advanced.

35. The method of claim 31, further comprising partially embedding the mesh in the electrically insulating material.

36. The method of claim 31, wherein the method is a roll-to-roll process.
